(19) United States
(12) Patent Application Publication
(10) Pub. No.: US 2010/0275819 A1
(43) Pub. Date: Nov. 4, 2010

(54) WIRELESS KEYBOARD DESK

(76) Inventor: LISA PRIEST, Broken Arrow, OK (US)

Correspondence Address: LAW OFFICE OF JERRY D. HAYNES , P.A, P.O. Box 350392, Fort Lauderdale, FL, 33335, US

(21) Appl. No.: 12/432,754

(22) Filed: Apr. 30, 2009

(51) Int. Cl. A47B 21/00; A47B 85/06; A47B 37/00; A47B 3/00; H05K 7/00

(52) U.S. Cl. 108/14; 108/50.11; 361/679.08

(57) ABSTRACT

The present invention relates to a wireless keyboard desk that includes: a platform; a wireless keyboard within the platform; a supporting base; and an internal opening. The platform may also include extendable mouse pads. In one exemplary embodiment, the wireless keyboard desk includes an over flap, where the over flap covers and closes the keyboard desk converting the desk to a portable case that may also include a carrying strap. The supporting base may include at least two foldable legs that extend from the bottom surface of the keyboard desk. The internal opening receives a laptop computer that may be opened for use or stored in a closed position.

### BACKGROUND OF THE INVENTION

1. Field of Invention

The present invention relates to a wireless keyboard desk combination.

2. Description of Related Art

Computer accessories exist in abundance to assist computer users with various tasks associated with computing. Specially designed desks, tables, chairs and props have been developed to provide various setup means for an individual computer. Accessories exist for both desktop computers and laptop computers.

Laptop computers provide users with a means to portably access and use their computers. Consequently the use of laptops has increased significantly over recent years due to advances in technology related thereto. The laptop computer typically includes a computer screen, mouse and a keyboard within one compact device. One drawback to the use of laptops relates to the keyboard size that is usually associated with a laptop. A conventional keyboard used with a desktop computer has a larger size and provides a typist with a broader range and scope of movement. The larger keyboard is especially useful in addressing ergonomic concerns as related to the use of laptop computers.

Another drawback to the use of laptops is having a table or an appropriate height desk in order to utilize the laptop. As is obvious by its name, the laptop may be simply placed upon a person's lap then used in that manner, however over an extended period of time a person may develop ergonomic problems associated with continuous use of a laptop on one's lap. Therefore it would be advantageous to have a computer setup specifically designed for laptop computer users that address some of the ergonomic concerns associated with the above drawbacks.

### SUMMARY OF THE INVENTION

The present invention relates to a wireless keyboard desk comprising: a platform; a wireless keyboard within the platform; a supporting base; and an internal opening. The platform may also include extendable mouse pads. In one exemplary embodiment, the wireless keyboard desk includes an over flap, where the over flap covers and closes the keyboard desk converting the desk to a portable case that may also include a carrying strap. The supporting base may include at least two foldable legs that extend from the bottom surface of the keyboard desk. The internal opening receives a laptop computer that may be opened for use or stored in a closed position.

### DESCRIPTION OF DRAWINGS

FIG. 1 shows a prospective view of the wireless keyboard desk component according to the present invention.

FIG. 2 shows a side view of the wireless keyboard desk according to the present invention.

### DETAILED DESCRIPTION

The present invention relates to a wireless keyboard desk utilized with a laptop computer that provides a means to place, store and transport a laptop computer. The wireless keyboard desk according to the present invention also addresses ergonomic concerns that may be associated with the use of a laptop computer.

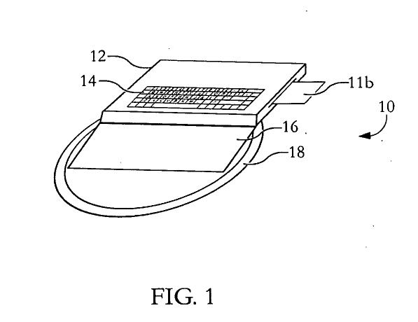

A wireless keyboard desk configuration 10 is shown in FIG. 1. The wireless keyboard desk provides a standard size keyboard that may be utilized with a laptop computer. The wireless keyboard 10 also includes a compartment that stores the laptop while not in use within the wireless keyboard desk. The top of the wireless keyboard desk 10 is depicted in FIG. 1 and includes a standard sized keyboard 14 mounted across a platform 12. The wireless keyboard desk 10 also includes mouse pads 11a, 11b that extend horizontally from either side of the desk 10 to provide an area for placement and movement of a conventional computer mouse. A strap 18 may also be attached to the wireless keyboard platform 12 with an over flap 16 which extends over the keyboard 14 when the keyboard 14 is stored and while transporting the desk 10. The wireless keyboard desk 10 therefore provides a consumer with a multi-functional laptop desk 10 equipped with a standardized wireless keyboard 14 with multiple USB ports.

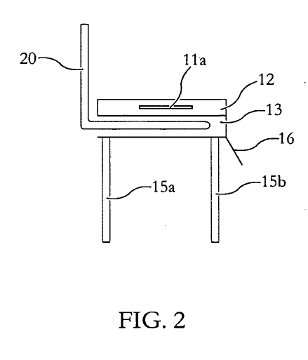

FIG. 2 depicts the wireless keyboard desk 10 wherein the platform 12 is shown with a side view that reveals an opening 13. A laptop computer 20 may be inserted into the opening 13 whereas the laptop computer 20 may be put in the open position therefore making the screen of the laptop visible to the user or the laptop computer 20 may be placed in the close position and enclosed in the opening 13 under platform 12. The laptop desk 10 may come equipped with legs that extend from the bottom surface of the wireless keyboard desk. Legs 15a, 15b are depicted in FIG. 2. The legs 15a, 15b although being depicted as a pair, may be up to four legs at each corner of the bottom surface. These legs 15a, 15b extend to provide a supporting base for the wireless keyboard desk 10.

The flap 16 extends over the wireless keyboard desk 10 and protects the keyboard 14 while transporting. The flap 16 encloses the keyboard desk 10 and therefore provides a means to store a laptop computer within the opening 13 in addition to the keyboard platform 12. The keyboard desk 10 may be made of wooden materials or other durable materials that can support the wireless keyboard 14 and provide a means to store the laptop. The preferred embodiment of the wireless keyboard desk 10 would include a lightweight material therefore making it conducive for portability. The wireless keyboard desk 10 may therefore be very useful for travelers, businessmen, and students who may use a laptop computer on a daily basis. The wireless keyboard desk 10 converts to a carrying case and can be transported through various venues. When the wireless keyboard desk 10 is in a closed position for transportation, it may resemble a briefcase or a simple carrying case therefore making it especially easy for travel purposes.

The instant invention has been shown and described in what is considered to be the most practical and preferred embodiments. It is recognized, however, that departures may be made there from within the scope of the invention and that obvious modifications will occur to a person skilled in the art.

What is claimed is:

1. A wireless keyboard desk comprising:
a. a platform;
b. a wireless keyboard within the platform;
c. a supporting base; and
d. an internal opening.

2. The wireless keyboard desk according to claim 1, wherein the platform also includes extendable mouse pads.

3. The wireless keyboard desk according to claim 1, further comprising an over flap, where said over flap covers and closes the keyboard desk converting the desk to a portable case; and a carrying strap.

4. The wireless keyboard desk according to claim 1, wherein said supporting base includes at least two foldable legs that extend from the bottom surface of the keyboard desk.

5. The wireless keyboard desk according to claim 1, wherein said opening receives a laptop computer.

6. The wireless keyboard desk according to claim 1, where said desk is constructed of a lightweight material.

7. The wireless keyboard desk according to claim 4, wherein said at least two foldable legs are adjustable in height.
